(19) United States
(12) Patent Application Publication
(10) Pub. No.: US 2025/0149456 A1
(43) Pub. Date: May 8, 2025

(54) SEMICONDUCTOR PACKAGE AND METHOD FOR MANUFACTURING THE SAME

(71) Applicant: SAMSUNG ELECTRONICS CO., LTD., SUWON-SI (KR)

(72) Inventors: Young-Ja KIM, Suwon-si (KR); Sun Won KANG, Suwon-si (KR); Mi-Na CHOI, Suwon-si (KR)

(21) Appl. No.: 18/670,911

(22) Filed: May 22, 2024

(30) Foreign Application Priority Data
Nov. 6, 2023 (KR) 10-2023-0151509

(51) Int. Cl. H01L 23/538; H01L 21/56; H01L 23/00; H01L 23/31; H01L 25/065

(52) U.S. Cl. CPC H01L 23/5384; H01L 21/56; H01L 23/3128; H01L 24/13; H01L 24/16; H01L 24/17; H01L 25/0655; H01L 2224/13111; H01L 2224/13116; H01L 2224/13139; H01L 2224/13144; H01L 2224/13147; H01L 2224/13155; H01L 2224/16225; H01L 2224/1703; H01L 2224/17519; H01L 2924/0132; H01L 2924/0133

(57) ABSTRACT

A semiconductor package includes a substrate having a vent hole defined therein. Semiconductor chips are mounted on an upper surface of the substrate. Chip connection terminals are disposed between the substrate and the semiconductor chips. Substrate connection terminals are disposed on a lower surface of the substrate. A plated layer includes a vertical heat-dissipation layer on an inner wall of the vent hole, a first heat-dissipation layer on the upper surface of the substrate and connected to at least one of the chip connection terminals and a second heat-dissipation layer on the lower surface of the substrate and connected to at least one of the substrate connection terminals. An encapsulant covers the upper surface of the substrate, the chip connection terminals, and the semiconductor chips, and fills a space between the semiconductor chips and the substrate. The encapsulant is on the plated layer and fills the vent hole.

### CROSS-REFERENCE TO RELATED APPLICATION

This application claims priority under 35 U.S.C. § 119 to Korean Patent Application No. 10-2023-0151509, filed on Nov. 6, 2023 in the Korean Intellectual Property Office, the disclosure of which is incorporated by reference in its entirety herein.

### 1. TECHNICAL FIELD

The present disclosure relates to a semiconductor package and a method for manufacturing the same.

### 2. DISCUSSION OF RELATED ART

As the size of a semiconductor chip has become increasingly miniaturized, the occurrence of a heat generation problem while the semiconductor chip is operating has increased. Therefore, an increased heat dissipation function of a semiconductor chip package is desired.

When molding a mounted semiconductor chip with a molding material, voids may be generated between an interposer and the semiconductor chip and/or between semiconductor chips that are spaced apart from each other. To reduce the generation of the voids, a vent hole may be formed.

### SUMMARY

An embodiment of the present disclosure is to provide a semiconductor package with an increased heat dissipation function.

Another purpose of an embodiment of the present disclosure is to provide a method for manufacturing a semiconductor package with increased heat dissipation ability.

Purposes according to the present disclosure are not limited to the above-mentioned purpose. Other purposes and advantages according to embodiments of the present disclosure that are not mentioned may be understood based on following descriptions, and may be more clearly understood based on embodiments according to the present disclosure. Further, it will be easily understood that the purposes and advantages according to embodiments of the present disclosure may be realized using means shown in the claims or combinations thereof.

According to an embodiment of the present disclosure, a semiconductor package includes a substrate having a vent hole defined therein. A plurality of semiconductor chips is mounted on an upper surface of the substrate. A plurality of chip connection terminals is disposed between the substrate and the plurality of semiconductor chips. A plurality of substrate connection terminals is disposed on a lower surface of the substrate. A plated layer includes a vertical heat-dissipation layer disposed on an inner wall of the vent hole. A first heat-dissipation layer is disposed on the upper surface of the substrate and is connected to at least one of the plurality of chip connection terminals. A second heat-dissipation layer is disposed on the lower surface of the substrate and is connected to at least one of the plurality of substrate connection terminals. An encapsulant covers the upper surface of the substrate, the plurality of chip connection terminals, and the plurality of semiconductor chips. The encapsulant fills a space between the plurality of semiconductor chips and the substrate. The encapsulant is disposed on the plated layer and fills the vent hole.

According to an embodiment of the present disclosure, a semiconductor package includes a substrate having a vent hole defined therein. A plurality of semiconductor chips is mounted on an upper surface of the substrate. A plurality of chip connection terminals is disposed between the substrate and the plurality of semiconductor chips. The plurality of chip connection terminals connects the substrate and the plurality of semiconductor chips to each other. A plurality of substrate connection terminals is disposed on a lower surface of the substrate. A plated layer includes a vertical heat-dissipation layer disposed on an inner wall of the vent hole. The vertical heat-dissipation layer of the plated layer connects at least one of the plurality of chip connection terminals and at least one of the plurality of substrate connection terminals to each other. An encapsulant covers the upper surface of the substrate, the plurality of chip connection terminals, and the plurality of semiconductor chips. The encapsulant fills a space between the plurality of semiconductor chips and the substrate. The encapsulant is disposed on the plated layer and fills the vent hole.

According to an embodiment of the present disclosure, a method for manufacturing a semiconductor package includes providing a substrate. The substrate has a vent hole defined therein. The substrate includes a plated layer. The plated layer includes a vertical heat-dissipation layer disposed on an inner wall of the vent hole, a first heat-dissipation layer disposed on an upper surface of the substrate, and a second heat-dissipation layer disposed on a lower surface of the substrate. A plurality of semiconductor chips having chip connection terminals attached thereto is mounted onto the upper surface of the substrate. An encapsulant is formed that covers the upper surface of the substrate, the plurality of chip connection terminals, and the plurality of semiconductor chips. The encapsulant fills a space between the plurality of semiconductor chips and the substrate, and fills the vent hole. A plurality of substrate connection terminals is on the lower surface of the substrate.

Specific details of some embodiments are included in the detailed description and drawings.

However, aspects of the present disclosure are not restricted to those set forth herein. The above and other aspects of embodiments of the present disclosure will become more apparent to one of ordinary skill in the art to which the present disclosure pertains by referencing the detailed description of the present disclosure given below.

### BRIEF DESCRIPTION OF DRAWINGS

The above and other aspects and features of embodiments of the present disclosure will become more apparent by describing in detail some embodiments thereof with reference to the attached drawings, in which:

FIG. 1 is a top view of a semiconductor package according to an embodiment of the present disclosure.

FIG. 2 is a cross-sectional view taken along a line A-A in FIG. 1 according to an embodiment of the present disclosure.

FIG. 3 is a cross-sectional view taken along a line B-B in FIG. 2 according to an embodiment of the present disclosure.

FIG. 4 is a diagram for illustrating a semiconductor package according to an embodiment of the present disclosure.

FIG. 5 is a cross-sectional view taken along a line C-C in FIG. 4 according to an embodiment of the present disclosure.

FIG. 6 is a diagram for illustrating a semiconductor package according to an embodiment of the present disclosure.

FIG. 7 is a diagram for illustrating a semiconductor package according to an embodiment of the present disclosure.

FIGS. 8 to 10 are diagrams for illustrating a method for manufacturing a semiconductor package according to some embodiments of the present disclosure.

FIG. 11 is a flowchart for illustrating a method for manufacturing a semiconductor package according to an embodiment of the present disclosure.

FIG. 12 is a diagram for illustrating a method for manufacturing a semiconductor package according to an embodiment of the present disclosure.

FIG. 13 is a flowchart for illustrating a method for manufacturing a semiconductor package according to an embodiment of the present disclosure.

FIG. 14 and FIG. 15 are diagrams for illustrating a method for manufacturing a semiconductor package according to some embodiments of the present disclosure.

FIG. 16 is a flowchart for illustrating a method for manufacturing a semiconductor package according to an embodiment of the present disclosure.

FIG. 17 is a diagram for illustrating a method for manufacturing a semiconductor package according to an embodiment of the present disclosure.

FIG. 18 is a flowchart for illustrating a method for manufacturing a semiconductor package according to an embodiment of the present disclosure.

### DETAILED DESCRIPTIONS OF EMBODIMENTS

Advantages and features of the present disclosure, and a method of achieving the advantages and features will become apparent with reference to non-limiting embodiments described later in detail together with the accompanying drawings. However, embodiments of the present disclosure are not limited to the described embodiments, but may be implemented in various different forms.

For simplicity and clarity of illustration, elements in the drawings may not be drawn to scale. The same reference numbers in different drawings represent the same or similar elements, and as such perform similar functionality. Further, descriptions and details of well-known steps and elements are omitted for simplicity of the description. Furthermore, in the following detailed description of embodiments of the present disclosure, numerous specific details are set forth to provide a thorough understanding of the present disclosure. However, it will be understood that embodiments of the present disclosure may be practiced without these specific details. In other instances, well-known methods, procedures, components, and circuits have not been described in detail so as not to unnecessarily obscure aspects of embodiments of the present disclosure. Examples of various embodiments are illustrated and described further below. It will be understood that the description herein is not intended to limit the claims to the described embodiments. On the contrary, it is intended to cover alternatives, modifications, and equivalents as may be included within the spirit and scope of embodiments of the present disclosure.

A shape, a size, a ratio, an angle, a number, etc. disclosed in the drawings for illustrating embodiments of the present disclosure may be illustrative, and embodiments of the present disclosure are not necessarily limited thereto.

The terminology used herein is directed to the purpose of describing particular embodiments only and is not intended to be limiting of embodiments of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list.

It will also be understood that when a first element or layer is referred to as being present “on” a second element or layer, the first element may be disposed directly on the second element or may be disposed indirectly on the second element with a third element or layer being disposed between the first and second elements or layers. When a first element or layer is referred to as being present “directly on” a second element or layer, no intervening elements may be disposed between the first and second elements or layers. It will also be understood that when a first element or layer is referred to as being present “under” a second element or layer, the first element may be disposed directly under the second element or may be disposed indirectly under the second element with a third element or layer being disposed between the first and second elements or layers.

It will be understood that when an element or layer is referred to as being “connected to”, or “coupled to” another element or layer, it may be directly connected to or coupled to another element or layer, or one or more intervening elements or layers therebetween may be present. When an element or layer is referred to as being “directly connected to”, or “directly coupled to” another element or layer, no intervening elements or layers may be present therebetween. In addition, it will also be understood that when an element or layer is referred to as being “between” two elements or layers, it may be the only element or layer between the two elements or layers, or one or more intervening elements or layers therebetween may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of embodiments of the present disclosure.

Spatially relative terms, such as “beneath,” “below,” “lower,” “under,” “above,” “upper,” and the like, may be used herein for ease of illustration to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

The features of the various embodiments of the present disclosure may be partially or entirely combined with each other, and may be technically associated with each other or operate with each other. The described embodiments may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

Hereinafter, embodiments of the present disclosure are described in detail with reference to the attached drawings.

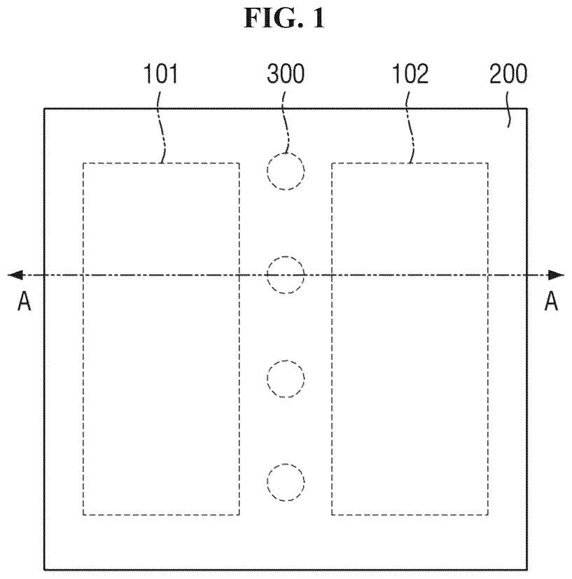

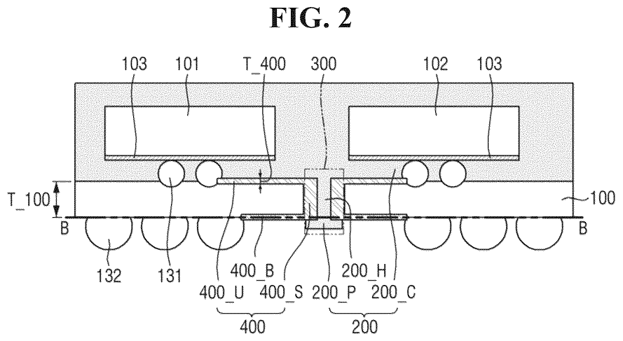

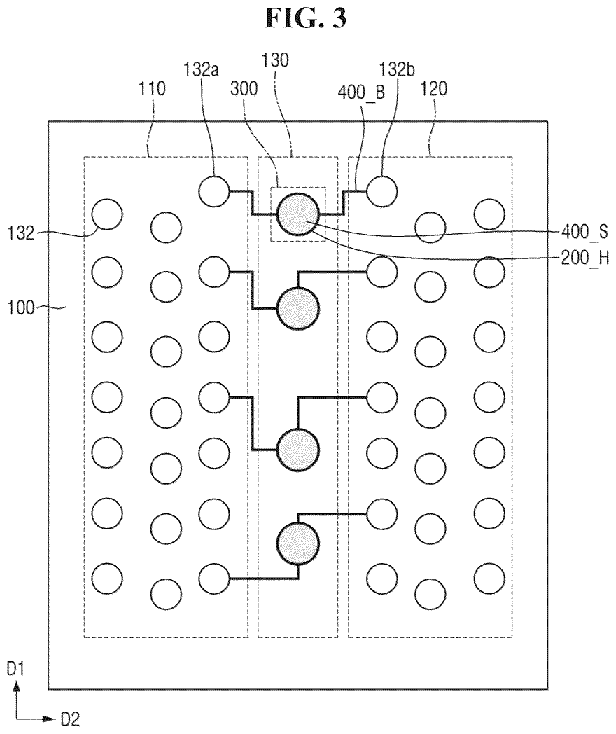

FIG. 1 is a top view of a semiconductor package according to some embodiments of the present disclosure. FIG. 2 is a cross-sectional view cut along a line A-A in FIG. 1. FIG. 3 is a cross-sectional view cut along a line B-B in FIG. 2.

Referring to FIGS. 1 to 3, in an embodiment the semiconductor package may include a substrate 100, first and second semiconductor chips 101 and 102, a chip connection terminal 131, a substrate connection terminal 132, and an encapsulant 200.

In an embodiment, the substrate 100 may be a package substrate, for example, a printed circuit board or a ceramic substrate. The substrate 100 may have an upper surface and a lower surface opposite to each other (e.g., in a thickness direction of the substrate 100). The chip connection terminal 131 may be disposed on (e.g., disposed directly thereon) the upper surface of the substrate 100. In an embodiment, a plurality of chip connection terminals 131 may be disposed on the upper surface of the substrate 100. The first and second semiconductor chips 101 and 102 may be mounted on the upper surface of the substrate 100, and the substrate connection terminal 132 may be disposed on (e.g., disposed directly thereon) the lower surface of the substrate 100.

In an embodiment, the substrate 100 may include a first area 110 on which the first semiconductor chip 101 is mounted and a second area 120 on which the second semiconductor chip 102 is mounted. The substrate 100 may include a third area 130 between the first area 110 and the second area 120 (e.g., in the second direction D2). In an embodiment, the third area 130 may include a vent hole 300. In an embodiment, the first area 110 and the second area 120 may extend longitudinally in a first direction D1. The vent holes 300 may be arranged along the first direction D1 and within the third area 130.

As described later, a plated layer 400 may extend along a surface of the substrate 100. The vent hole 300 may be defined in the substrate 100. For example, the vent hole 300 may extend through the substrate 100. In an embodiment, a plurality of vent holes 300 may be defined in the substrate 100.

The vent hole 300 may extend through an entirety of the substrate 100 (e.g., in a thickness direction of the substrate 100). The vent hole 300 may be formed to allow a liquid material, for example, the encapsulant 200 to be described later, to flow from the upper surface of the substrate 100 to the lower surface thereof. The vent hole 300 may serve as a passage through which the liquid encapsulant 200 flows.

FIG. 1 and FIG. 3 show four vent holes 300 defined in the substrate 100. However, embodiments of the present disclosure are not necessarily limited thereto and the number of the plurality of vent holes 300 may vary. The vent hole 300 may be formed under a plurality of semiconductor chips, such as first and second semiconductor chips 101 and 102, mounted on the upper surface of the substrate 100. However, embodiments of the present disclosure are not necessarily limited thereto. In FIG. 1 and FIG. 3, an embodiment in which spacings between adjacent vent holes 300 are equal to each other is shown. However, embodiments of the present disclosure are not necessarily limited thereto. For example, in some embodiments the spacings between the adjacent vent holes 300 may not be uniform.

The plated layer 400 may be disposed along the surface of the substrate 100. In an embodiment, the plated layer 400 may include a vertical heat-dissipation layer 400_S disposed on (e.g., disposed directly thereon) an inner wall of the vent hole 300, a first heat-dissipation layer 400_U which is disposed on (e.g., disposed directly thereon) the upper surface of the substrate 100 and is connected to (e.g., directly connected thereto) at least one of the chip connection terminals 131, and a second heat-dissipation layer 400_B which is disposed on the lower surface of the substrate 100 and is connected to (e.g., directly connected thereto) at least one of the substrate connection terminals 132.

In an embodiment, the plated layer 400 may include a metal material. For example, the plated layer 400 may include copper (Cu), nickel (Ni), gold (Au), etc. In an embodiment, a thickness T_400 of the plated layer 400 may be less than a thickness T_100 of the substrate 100. In an embodiment, the thicknesses T_400 of the vertical heat-dissipation layer 400_S, the first heat-dissipation layer 400_U, and the second heat-dissipation layer 400_B may not be equal to each other. For example, the thickness T_400 of the plated layer 400 may not be uniform. The plated layer 400 may receive heat generated from the plurality of semiconductor chips, such as the first and second semiconductor chips 101 and 102, and discharge the heat to an outside (e.g., the external environment).

In an embodiment, the plated layer 400 may be connected to the semiconductor chip from which a larger amount of heat is generated. For example, in an embodiment the first semiconductor chip 101, among the plurality of semiconductor chips, may generate a larger amount of heat and the plated layer 400 may be connected thereto. Furthermore, the plated layer 400 may be disposed intensively on a portion (e.g., a hot spot) of the first semiconductor chip 101 in which a larger amount of heat is generated, thereby increasing a heat dissipation function.

The plurality of semiconductor chips, such as the first and second semiconductor chips 101 and 102, may be mounted on the upper surface of the substrate 100. In an embodiment, the plurality of semiconductor chips, such as the first and second semiconductor chips 101 and 102, may be mounted on a central area of the upper surface of the substrate 100 via adhesive means. However, embodiments of the present disclosure are not necessarily limited thereto. In an embodiment, the adhesive means may include, for example, at least one of liquid epoxy, adhesive tape, or a conductive medium.

Each of the plurality of semiconductor chips, such as the first and second semiconductor chips 101 and 102, may include a pattern 103 (e.g., a conductive pattern). The pattern 103 may be used to electrically connect each of the plurality of semiconductor chips, such as the first and second semiconductor chips 101 and 102, to other components. For example, in an embodiment the pattern 103 may not be covered with a lower surface of each of the first and second semiconductor chips 101 and 102 so as to be exposed. For example, in an embodiment the pattern 103 may include a metal material such as copper (Cu) or aluminum (Al). However, embodiments of the present disclosure are not necessarily limited thereto.

In FIGS. 1-3, an embodiment in which two semiconductor chips, such as the first and second semiconductor chips 101 and 102, are included in the semiconductor package is described. However, embodiments of the present disclosure are not necessarily limited thereto. For example, in some embodiments the plurality of semiconductor chips included in the semiconductor package may be three or more semiconductor chips, and may further include semiconductor chips stacked vertically.

The chip connection terminal 131 may attach each of the plurality of semiconductor chips, such as the first and second semiconductor chips 101 and 102, to the upper surface of the substrate 100. Each of the plurality of semiconductor chips, such as the first and second semiconductor chips 101 and 102, on which the chip connection terminal 131 has been formed is mounted on the upper surface of the substrate 100, so that each of the plurality of semiconductor chips may be electrically connected to the substrate 100 via the chip connection terminal 131. For example, in an embodiment the chip connection terminal 131 may include a bump. In an embodiment, the bump may include, for example, gold, silver, nickel, copper, tin, or alloys thereof. For example, the bump 140 may include copper-nickel-lead (Cu—Ni—Pb), copper-nickel-gold (Cu—Ni—Au), copper-nickel (Cu—Ni), nickel-gold (Ni—Au), or nickel-silver (Ni—Ag), etc. In an embodiment, the chip connection terminal 131 connected to the plated layer 400 may be connected to (e.g., electrically connected thereto) a ground.

The substrate connection terminal 132 may be disposed on the lower surface of the substrate 100. In an embodiment, the substrate connection terminal 132 may electrically connect the semiconductor package to either a module mode module board or a main circuit board. In an embodiment, the substrate connection terminal 132 may be, for example, a solder ball or a conductive bump. However, embodiments of the present disclosure are not necessarily limited thereto. In an embodiment in which the substrate connection terminal 132 is a solder ball, a solder ball pad may be disposed between the substrate connection terminal 132 and the substrate 100. The substrate connection terminal 132 connected to the plated layer 400 may be connected to (e.g., electrically connected thereto) a ground.

In an embodiment, the substrate connection terminal 132 may include first substrate connection terminals 132a which are disposed on the first area 110 and arranged in a plurality of columns, and second substrate connection terminals 132b which are disposed on the second area 120 and arranged in a plurality of columns. The plated layer 400 may connect (e.g., electrically connect) at least one of the plurality of the first substrate connection terminals 132a and at least one of the plurality of the second substrate connection terminals 132b to each other.

The encapsulant 200 may include an encapsulant body 200_C, an encapsulant hole portion 200_H, and an encapsulant protrusion 200_P. In an embodiment, the encapsulant 200 may cover the upper surface of the substrate 100, the chip connection terminal 131, and the plurality of semiconductor chips, such as upper, lower and lateral sides of the first and second semiconductor chips 101 and 102. The encapsulant 200 may cover the plurality of semiconductor chips, such as the first and second semiconductor chips 101 and 102, and the plated layer 400. The encapsulant 200 may fill a space between the first and second semiconductor chips 101 and 102 and the substrate 100. The encapsulant 200 may fill (e.g., completely fill) the vent hole 300.

In an embodiment, an upper surface of the encapsulant 200 may have a vertical level greater than or equal to (e.g., coplanar with) a vertical level of an upper surface of each of the plurality of semiconductor chips, such as the first and second semiconductor chips 101 and 102. However, embodiments of the present disclosure are not necessarily limited thereto. FIG. 2 shows an example in which the upper surface of the encapsulant 200 has a vertical level higher than that that of the upper surface of each of the plurality of semiconductor chips, such as the first and second semiconductor chips 101 and 102. However, in an embodiment the upper surface of the encapsulant 200 may be coplanar with (e.g., in a vertical direction) the upper surface of each of the plurality of semiconductor chips, such as the first and second semiconductor chips 101 and 102.

In an embodiment, the encapsulant 200 may be formed to fill the space between the plurality of semiconductor chips, such as the first and second semiconductor chips 101 and 102, and the substrate 100, and thus may serve to protect the chip connection terminal 131 and to increase adhesion between the plurality of semiconductor chips and the substrate 100. Furthermore, the encapsulant 200 may maintain an appearance of the semiconductor package and protect the plurality of semiconductor chips from external physical shock or moisture. For example, in an embodiment the encapsulant 200 may include at least one of liquid epoxy molding compound (EMC), silicone resin, polyimide, or equivalents thereto. However, embodiments of the present disclosure are not necessarily limited thereto.

The encapsulant 200 may flow from the upper surface of the substrate 100 to the lower surface thereof through the vent hole 300 defined in the substrate 100. In a molding process, when injecting the encapsulant 300, voids may be generated. In this regard, the encapsulant 200 may flow into the vent hole 300. As the encapsulant 200 flows into the vent hole 300, the voids trapped under the plurality of semiconductor chips, such as the first and second semiconductor chips 101 and 102, may be removed. A plurality of vent holes 400 may increase a flow speed of the encapsulant 200 and increase the void removal efficiency. In an embodiment, the encapsulant 200 may flow into the vent hole 300 and then out of the vent hole 300 and thus form the encapsulant protrusion 200_P.

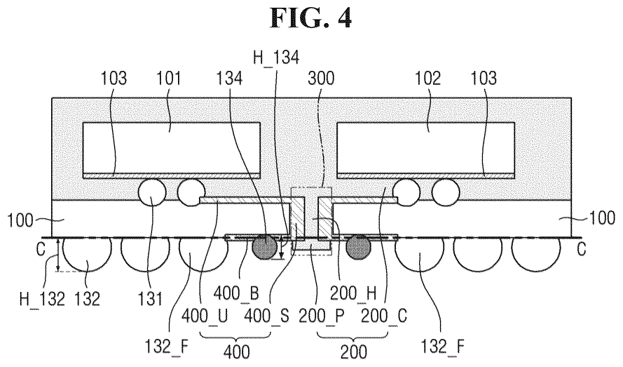

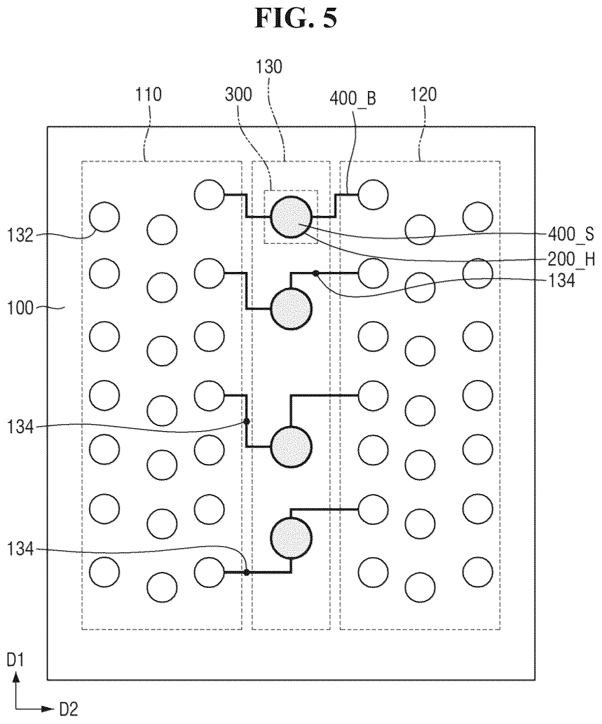

FIG. 4 is a diagram for illustrating a semiconductor package according to an embodiment of the present disclosure. FIG. 5 is a cross-sectional view cut along a line C-C in FIG. 4. For convenience of description, FIG. 4 and FIG. 5 are described mainly based on differences thereof from those as described above with reference to FIGS. 1 to 3 and a repeated description of similar or identical elements may be omitted for economy of description.

Referring to FIG. 4 and FIG. 5, in some embodiments the semiconductor package may include the substrate 100, the first and second semiconductor chips 101 and 102, the chip connection terminal 131, the substrate connection terminal 132, the encapsulant 200, and a substrate-plated layer connection terminal 134.

In an embodiment, the substrate-plated layer connection terminal 134 may be disposed between the vent hole 300 and the substrate connection terminal 132_F which is located closest to the vent hole 300 among the plurality of substrate connection terminals 132. The substrate-plated layer connection terminal 134 may be connected to (e.g., directly connected thereto) the second heat-dissipation layer 400_B. The substrate-plated layer connection terminal 134 may be disposed on (e.g., disposed directly thereon) the second heat-dissipation layer 400_B. The substrate-plated layer connection terminal 134 may receive heat generated from the plurality of semiconductor chips, such as the first and second semiconductor chips 101 and 102, and discharge the heat to the outside (e.g., an external environment).

In an embodiment, a height H_134 (e.g., length in the vertical direction) of the substrate-plated layer connection terminal 134 may be equal to a height H_132 (e.g., length in the vertical direction) of the substrate connection terminal 132, or may be less than the height H_132 of the substrate connection terminal 132. In an embodiment, the substrate-plated layer connection terminal 134 may include the same material as that of the substrate connection terminal 132. However, embodiments of the present disclosure are not necessarily limited thereto.

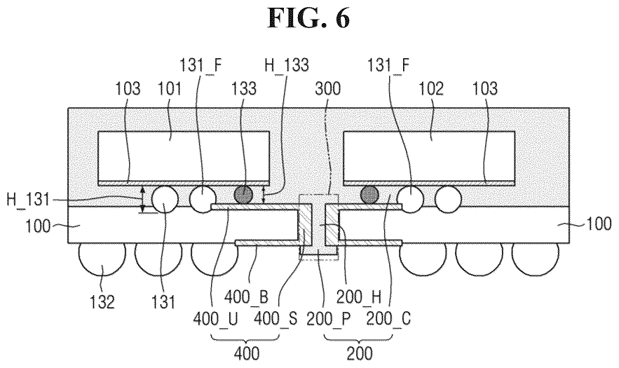

FIG. 6 is a diagram for illustrating a semiconductor package according to an embodiment of the present disclosure. For convenience of description, FIG. 6 is described mainly based on differences thereof from those as described above with reference to FIG. 2 and a repeated description of similar or identical elements may be omitted for economy of description.

Referring to FIG. 6, in an embodiment the semiconductor package may include the substrate 100, the first and second semiconductor chips 101 and 102, the chip connection terminal 131, the substrate connection terminal 132, the encapsulant 200, and a chip-plated layer connection terminal 133.

In an embodiment, the chip-plated layer connection terminal 133 may be disposed between the vent hole 300 and the chip connection terminal 131_F which is located closest to the vent hole 300 among the plurality of chip connection terminals 131. The chip-plated layer connection terminal 133 may be connected to the first heat-dissipation layer 400_U. The chip-plated layer connection terminal 133 may be disposed on the first heat-dissipation layer 400_U and receive heat generated from the plurality of semiconductor chips, such as the first and second semiconductor chips 101 and 102 and discharge the heat to the outside (e.g., an external environment).

In an embodiment, a height H_133 (e.g., length in the vertical direction) of the chip-plated layer connection terminal 133 may be equal to a height H_131 of the chip connection terminal 131, or may be less than the height H_131 of the chip connection terminal 131. In an embodiment, the chip-plated layer connection terminal 133 may include the same material as that of the chip connection terminal 131. However, embodiments of the present disclosure are not necessarily limited thereto.

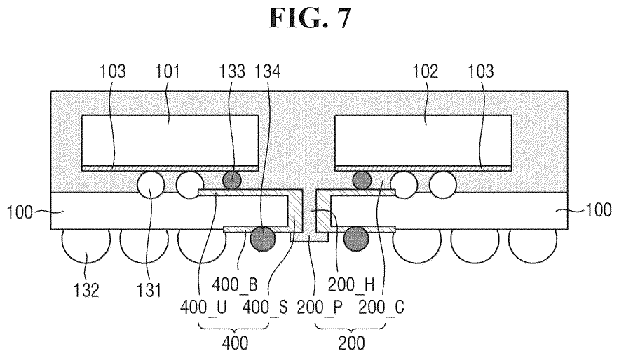

FIG. 7 is a diagram for illustrating a semiconductor package according to still yet another embodiment of the present disclosure. For convenience of description, FIG. 7 is described mainly based on differences thereof from those as described above with reference to FIG. 4 and FIG. 6.

Referring to FIG. 7, in an embodiment the semiconductor package may include the substrate 100, the first and second semiconductor chips 101 and 102, the chip connection terminal 131, the substrate connection terminal 132, the encapsulant 200, the substrate-plated layer connection terminal 134, and the chip-plated layer connection terminal 133.

In an embodiment, the substrate-plated layer connection terminal 134 may be disposed on (e.g., disposed directly thereon) the second heat-dissipation layer 400_B and receive heat generated from the plurality of semiconductor chips, such as the first and second semiconductor chips 101 and 102, and discharge the heat to the outside (e.g., an external environment).

In an embodiment, the chip-plated layer connection terminal 133 may be disposed on (e.g., disposed directly thereon) the first heat-dissipation layer 400_U and receive heat generated from the plurality of semiconductor chips, such as the first and second semiconductor chips 101 and 102, and discharge the heat to the outside (e.g., an external environment).

In an embodiment as shown in FIG. 7, the semiconductor package including both the substrate-plated layer connection terminal 134 and the chip-plated layer connection terminal 133 may more effectively receive the heat generated from the plurality of semiconductor chips, such as the first and second semiconductor chips 101 and 102, and more effectively discharge the heat to the outside (e.g., an external environment), compared to the semiconductor package including only chip-plated layer connection terminal 133 without the substrate-plated layer connection terminal 134, the semiconductor package including only the substrate-plated layer connection terminal 134 without the chip-plated layer connection terminal 133 or, a semiconductor package that does not include either of the substrate-plated layer connection terminal 134 and the chip-plated layer connection terminal 133.

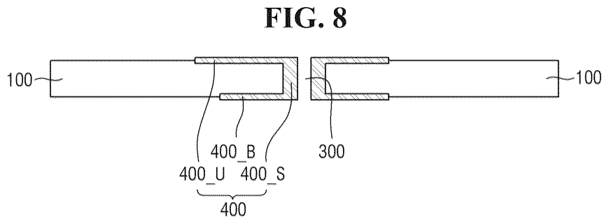

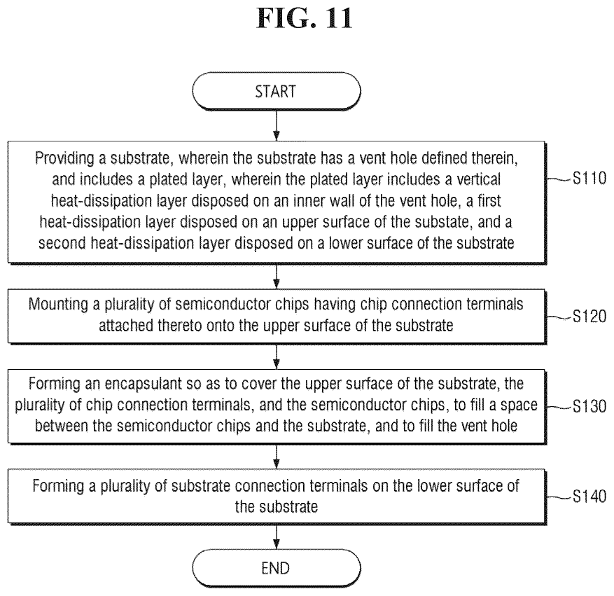

FIGS. 8 to 10 are diagrams for illustrating a method for manufacturing a semiconductor package according to some embodiments of the present disclosure. FIG. 11 is a flowchart for illustrating a method for manufacturing a semiconductor package according to some embodiments of the present disclosure.

Referring to FIG. 8 and FIG. 11, the substrate 100 is provided in block S110.

In an embodiment, the substrate 100 may include the vent hole 300 and the plated layer 400. The plated layer 400 may include the vertical heat-dissipation layer 400_S disposed on (e.g., disposed directly thereon) the inner wall of the vent hole 300, the first heat-dissipation layer 400_U disposed on (e.g., disposed directly thereon) the upper surface of the substrate, and the second heat-dissipation layer 400_B disposed on (e.g., disposed directly thereon) the lower surface of the substrate.

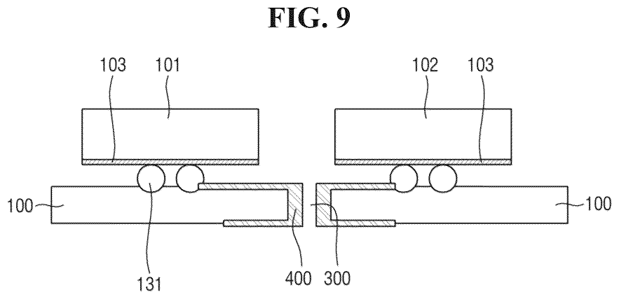

Next, referring to FIG. 9 and FIG. 11, each of the plurality of semiconductor chips, such as the first and second semiconductor chips 101 and 102, to which the chip connection terminals 131 have been attached is mounted on the upper surface of the substrate 100 in block S120.

In an embodiment, each of the plurality of semiconductor chips, such as the first and second semiconductor chips 101 and 102, may include the pattern 103 (e.g., a conductive pattern). The plurality of semiconductor chips may be electrically connected to the substrate 100 via the chip connection terminals 131. For example, in an embodiment the chip connection terminal 131 may include the bump. In an embodiment, the bump may include, for example, gold, silver, nickel, copper, tin, or alloys thereof. For example, the bump 140 may include copper-nickel-lead (Cu—Ni—Pb), copper-nickel-gold (Cu—Ni—Au), copper-nickel (Cu—Ni), nickel-gold (Ni—Au), or nickel-silver (Ni—Ag), etc. However, embodiments of the present disclosure are not necessarily limited thereto.

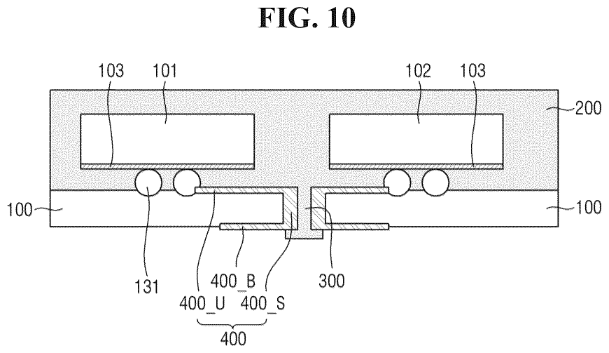

Next, referring to FIG. 10 and FIG. 11, the encapsulant 200 is formed in block S130.

In an embodiment, the encapsulant 200 may cover the upper surface of the substrate 100, the plurality of chip connection terminals 131, and the plurality of semiconductor chips, such as the first and second semiconductor chips 101 and 102, and may fill (e.g., completely fill) the space between the semiconductor chips, such as the first and second semiconductor chips 101 and 102, and the substrate 100, and may fill (e.g., completely fill) the vent hole.

Next, referring to FIG. 2 and FIG. 11, the plurality of substrate connection terminals 132 are formed on (e.g., formed directly thereon) the lower surface of the substrate 100 in block S140.

In an embodiment, the substrate connection terminal 132 may be a solder ball or a conductive bump. However, embodiments of the present disclosure are not necessarily limited thereto. In an embodiment in which the substrate connection terminal 132 is a solder ball1, a solder ball pad may be disposed between (e.g., directly disposed therebetween in a vertical direction) the substrate connection terminal 132 and the substrate 100.

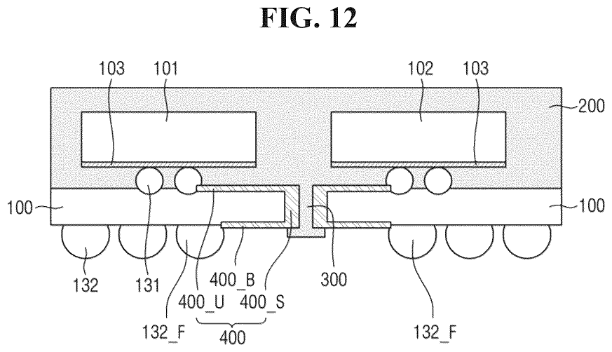

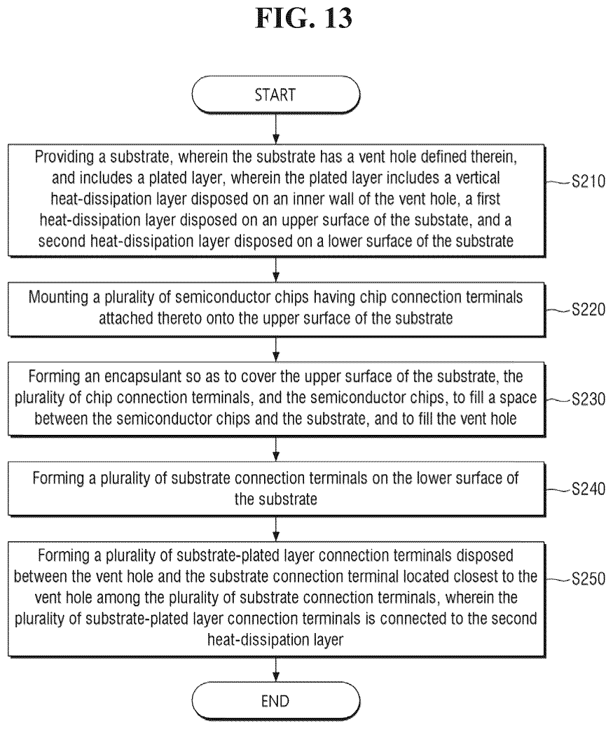

FIG. 12 is a diagram for illustrating a method for manufacturing a semiconductor package according to some embodiments of the present disclosure. FIG. 13 is a flowchart for illustrating a method for manufacturing a semiconductor package according to some embodiments of the present disclosure. For convenience of description, FIG. 12 and FIG. 13 are described based on differences thereof from those as described above with reference to FIGS. 8 to 11 and a repeated description of similar or identical elements may be omitted for economy of description.

Referring to FIG. 12 and FIG. 13, the substrate 100 is provided in block S210. In an embodiment, the plurality of semiconductor chips, such as the first and second semiconductor chips 101 and 102, are mounted on the upper surface of the provided substrate in block S220. In an embodiment, the encapsulant 200 is then formed so as to cover the upper surface of the substrate 100, the plurality of chip connection terminals 131, and the first and second semiconductor chips 101 and 102, and to fill (e.g., completely fill) the space between the first and second semiconductor chips 101 and 102 and the substrate 100, and fill (e.g., completely fill) the vent hole 300 in block S230. The plurality of substrate connection terminals 132 are formed on (e.g., formed directly thereon) the lower surface of the substrate 100 in block S240. For reference, FIG. 12 is a diagram showing a step following FIG. 10.

Next, referring to FIG. 4 and FIG. 13, a plurality of substrate-plated layer connection terminals 134 is formed on (e.g., formed directly thereon) the lower surface of the substrate 100 in block S250.

For example, in an embodiment the plurality of substrate-plated layer connection terminals 134 may be disposed between the vent hole 300 and the substrate connection terminal 132_F which is located closest to the vent hole 300 among the plurality of substrate connection terminals 132. The substrate-plated layer connection terminal 134 may be connected to (e.g., directly connected thereto) the second heat-dissipation layer 400_B.

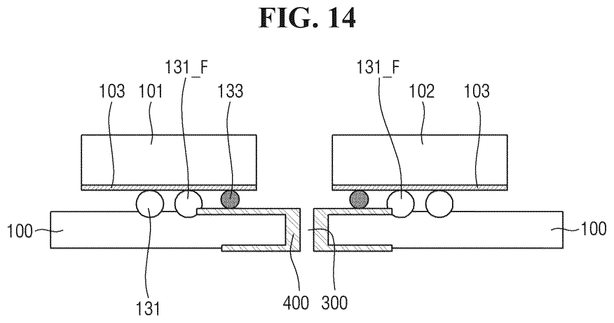

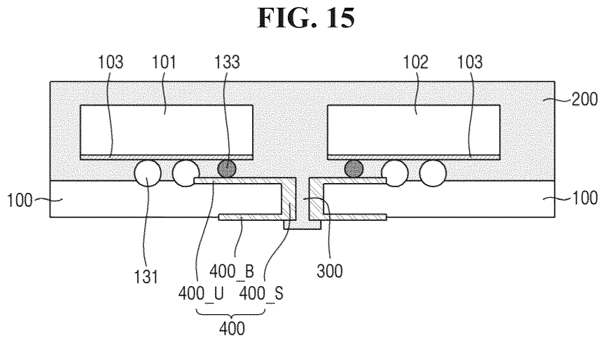

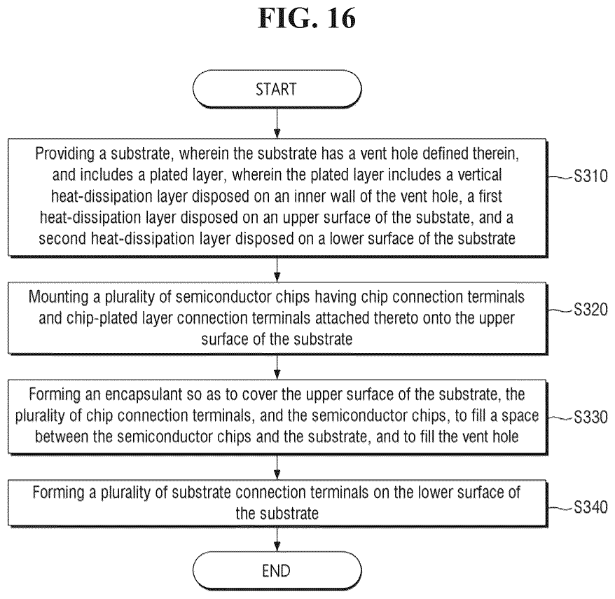

FIG. 14 and FIG. 15 are diagrams for illustrating a method for manufacturing a semiconductor package according to some embodiments of the present disclosure. FIG. 16 is a flowchart for illustrating a method for manufacturing a semiconductor package according to some embodiments of the present disclosure. For convenience of description, FIGS. 14 to 16 are described based on differences thereof from those described above with reference to FIGS. 8 to 11 and a repeated description of similar or identical elements may be omitted for economy of description.

Referring to FIG. 14 and FIG. 16, the substrate 100 is provided in block S310, and the plurality of semiconductor chips, such as the first and second semiconductor chips 101 and 102, are mounted on the upper surface of the provided substrate in S320. For reference, FIG. 14 is a diagram showing a step following FIG. 8.

In an embodiment, each of the plurality of semiconductor chips, such as the first and second semiconductor chips 101 and 102, may include the chip connection terminal 131 and the chip-plated layer connection terminal 133. In an embodiment, the chip connection terminal 131 and the chip-plated layer connection terminal 133 may be disposed on (e.g., disposed directly thereon) the lower surface of each of the plurality of semiconductor chips, such as the first and second semiconductor chips 101 and 102. The chip-plated layer connection terminal 133 may be disposed between the vent hole 300 and the chip connection terminal 131_F which is located closest to the vent hole 300 among the plurality of chip connection terminals 131. In an embodiment, the chip-plated layer connection terminal 133 may be connected to (e.g., directly connected thereto) the first heat-dissipation layer 400_U.

In an embodiment, referring to FIG. 15 and FIG. 16, the encapsulant 200 is then formed in block S330.

In an embodiment, the encapsulant 200 may cover the upper surface of the substrate 100, the plurality of chip connection terminals 131, the chip-plated layer connection terminal 133, and the first and second semiconductor chips 101 and 102, and may fill (e.g., completely fill) the space between the plurality of semiconductor chips and the substrate 100, and may fill (e.g., completely fill) the vent hole 300. In an embodiment, the substrate connection terminal 132 may be a solder ball or a conductive bump. However, embodiments of the present disclosure are not necessarily limited thereto.

Next, referring to FIG. 6 and FIG. 16, the plurality of substrate connection terminals 132 is formed on (e.g., formed directly thereon) the lower surface of the substrate 100 in block S340.

In an embodiment, the substrate connection terminal 132 may be a solder ball or a conductive bump. However, embodiments of the preset disclosure are not necessarily limited thereto. In an embodiment in which the substrate connection terminal 132 is a solder ball, the solder ball pad may be disposed between the substrate connection terminal 132 and the substrate 100 (e.g., disposed directly therebetween in the vertical direction).

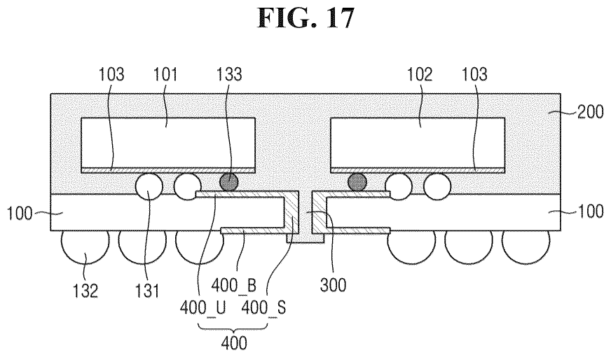

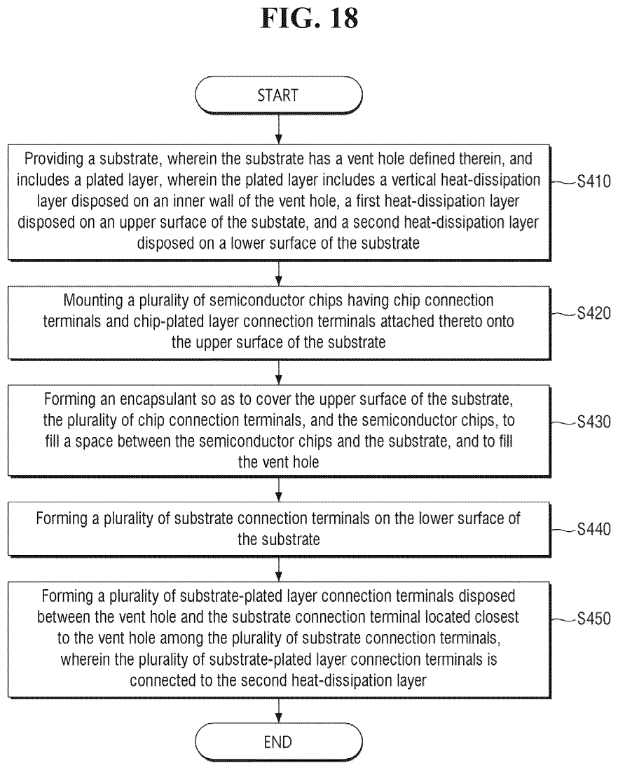

FIG. 17 is a diagram for illustrating a method for manufacturing a semiconductor package according to an embodiment of the present disclosure. FIG. 18 is a flowchart for illustrating a method for manufacturing a semiconductor package according to an embodiment of the present disclosure. For convenience of description, FIG. 17 and FIG. 18 are described based on differences thereof from those as described above with reference to FIGS. 14 to 16 and a repeated description of similar or identical elements may be omitted for economy of description.

Referring to FIG. 17 and FIG. 18, the substrate 100 is provided in block S410, and the plurality of semiconductor chips, such as the first and second semiconductor chips 101 and 102, are mounted on the upper surface of the substrate 100 in block S420. In an embodiment, the encapsulant 200 is formed in block S430, and the plurality of substrate connection terminals 132 are formed on (e.g., formed directly thereon) the lower surface of substrate 100 in block S440. For reference, FIG. 17 is a diagram showing a step following FIG. 15.

In an embodiment, each of the plurality of semiconductor chips 101 and 102, such as the first and second semiconductor chips, may include the chip connection terminal 131 and the chip-plated layer connection terminal 133. The chip-plated layer connection terminal 133 may be disposed between the vent hole 300 and the chip connection terminal 131_F which is located closest to the vent hole 300 among the plurality of chip connection terminals 131. The chip plated layer connection terminal 133 may be connected to (e.g., directly connected thereto) the first heat-dissipation layer 400_U. In an embodiment, the encapsulant 200 may cover the upper surface of the substrate 100, the plurality of chip connection terminals 131, the chip-plated layer connection terminal 133, and the first and second semiconductor chips 101 and 102, and may fill (e.g., completely fill) the space between the plurality of semiconductor chips, such as the first and second semiconductor chips 101 and 102, and the substrate 100, and may fill (e.g., completely fill) the vent hole 300. In an embodiment, the substrate connection terminal 132 may be a solder ball or a conductive bump. However, embodiments of the present disclosure are not necessarily limited thereto.

In an embodiment, referring to FIG. 4 and FIG. 18, a plurality of substrate-plated layer connection terminals 134 is formed on (e.g., formed directly thereon) the lower surface of the substrate 100 in block S450.

For example, in an embodiment each of the plurality of substrate-plated layer connection terminals 134 may be disposed between the vent hole 300 and the substrate connection terminal 132_F which is located closest to the vent hole 300 among the plurality of substrate connection terminals 132. In an embodiment, the substrate-plated layer connection terminal 134 may be connected to (e.g., directly connected thereto) the second heat-dissipation layer 400_B.

Although embodiments of the present disclosure have been described with reference to the accompanying drawings, embodiments of the present disclosure are not limited to the described embodiments, but may be implemented in various different forms. A person skilled in the art may appreciate that embodiments of the present disclosure may be practiced in other concrete forms without changing the technical spirit or essential characteristics of the present disclosure. Therefore, it should be appreciated that the described embodiments are not restrictive but illustrative in all respects.

What is claimed is:

1. A semiconductor package comprising:
a substrate having a vent hole defined therein;
a plurality of semiconductor chips mounted on an upper surface of the substrate;
a plurality of chip connection terminals disposed between the substrate and the plurality of semiconductor chips;
a plurality of substrate connection terminals disposed on a lower surface of the substrate;
a plated layer including:
a vertical heat-dissipation layer disposed on an inner wall of the vent hole;
a first heat-dissipation layer disposed on the upper surface of the substrate and connected to at least one of the plurality of chip connection terminals; and
a second heat-dissipation layer disposed on the lower surface of the substrate and connected to at least one of the plurality of substrate connection terminals; and
an encapsulant covering the upper surface of the substrate, the plurality of chip connection terminals, and the plurality of semiconductor chips, the encapsulant filling a space between the plurality of semiconductor chips and the substrate, wherein the encapsulant is disposed on the plated layer and fills the vent hole.

2. The semiconductor package of claim 1, wherein the substrate includes:
a first area, wherein a first semiconductor chip of the plurality of semiconductor chips is mounted in the first area;
a second area, wherein a second semiconductor chip of the plurality of semiconductor chips is mounted in the second area; and
a third area disposed between the first area and the second area, wherein the vent hole is defined in the third area.

3. The semiconductor package of claim 2, wherein:
each of the first area and the second area extends in a first direction; and
the vent hole includes a plurality of vent holes,
wherein the plurality of vent holes are arranged along the first direction.

4. The semiconductor package of claim 3, wherein the plurality of substrate connection terminals includes:
a plurality of first substrate connection terminals disposed on the first area, the plurality of substrate connection terminals is arranged in a first plurality of columns; and
a plurality of second substrate connection terminals disposed on the second area, the plurality of second substrate connection terminals is arranged in a second plurality of columns,
wherein the plated layer electrically connects at least one of the plurality of first substrate connection terminals and at least one of the plurality of second substrate connection terminals to each other.

5. The semiconductor package of claim 1, wherein each of the plurality of chip connection terminals and the plurality of substrate connection terminals is electrically connected to a ground.

6. The semiconductor package of claim 1, further comprising:
a plurality of chip-plated layer connection terminals disposed between the vent hole and a chip connection terminal of the plurality of chip connection terminals that is disposed closest to the vent hole,
wherein the plurality of chip-plated layer connection terminals is connected to the first heat-dissipation layer.

7. The semiconductor package of claim 6, further comprising:
a plurality of substrate-plated layer connection terminals, each of the plurality of substrate-plated layer connection terminals is disposed between the vent hole and a substrate connection terminal of the plurality of substrate connection terminals that is disposed closest to the vent hole,
wherein the plurality of substrate-plated layer connection terminals is connected to the second heat-dissipation layer.

8. The semiconductor package of claim 6, wherein a height of each of the plurality of chip-plated layer connection terminals is less than or equal to a height of each of the plurality of chip connection terminals.

9. The semiconductor package of claim 1, further comprising:
a plurality of substrate-plated layer connection terminals, each of the plurality of substrate-plated layer connection terminals is disposed between the vent hole and a substrate connection terminal of the plurality of substrate connection terminals that is disposed closest to the vent hole,
wherein the plurality of substrate-plated layer connection terminals is connected to the second heat-dissipation layer.

10. The semiconductor package of claim 9, wherein a height of each of the plurality of substrate-plated layer connection terminals is less than or equal to a height of each of the plurality of substrate connection terminals.

11. A semiconductor package comprising:
a substrate having a vent hole defined therein;
a plurality of semiconductor chips mounted on an upper surface of the substrate;
a plurality of chip connection terminals disposed between the substrate and the plurality of semiconductor chips, the plurality of chip connection terminals connecting the substrate and the plurality of semiconductor chips to each other;
a plurality of substrate connection terminals disposed on a lower surface of the substrate;
a plated layer including a vertical heat-dissipation layer disposed on an inner wall of the vent hole, wherein the vertical heat-dissipation layer of the plated layer connects at least one of the plurality of chip connection terminals and at least one of the plurality of substrate connection terminals to each other; and
an encapsulant covering the upper surface of the substrate, the plurality of chip connection terminals, and the plurality of semiconductor chips, the encapsulant filling a space between the plurality of semiconductor chips and the substrate, wherein the encapsulant is disposed on the plated layer and fills the vent hole.

12. The semiconductor package of claim 11, wherein the substrate includes:
a first area, wherein a first semiconductor chip of the plurality of semiconductor chips is mounted in the first area;
a second area, wherein a second semiconductor chip of the plurality of semiconductor chips is mounted in the second area; and
a third area disposed between the first area and the second area, wherein the vent hole is defined in the third area.

13. The semiconductor package of claim 11, wherein each of the plurality of chip connection terminals and the plurality of substrate connection terminals is electrically connected to a ground.

14. The semiconductor package of claim 11, wherein the encapsulant includes an epoxy molding compound (EMC).

15. The semiconductor package of claim 11, further comprising:
a plurality of substrate-plated layer connection terminals, each of the plurality of substrate-plated connection terminals is disposed between the vent hole and a substrate connection terminal of the plurality of substrate connection terminals that is disposed closest to the vent hole,
wherein the plurality of substrate-plated layer connection terminals is connected to the plated layer.

16. A method for manufacturing a semiconductor package, the method comprising:
providing a substrate, wherein the substrate has a vent hole defined therein, the substrate including a plated layer, wherein the plated layer includes a vertical heat-dissipation layer disposed on an inner wall of the vent hole, a first heat-dissipation layer disposed on an upper surface of the substrate, and a second heat-dissipation layer disposed on a lower surface of the substrate;
mounting a plurality of semiconductor chips having a plurality of chip connection terminals attached thereto onto the upper surface of the substrate;
forming an encapsulant covering the upper surface of the substrate, the plurality of chip connection terminals, and the plurality of semiconductor chips, the encapsulant filling a space between the plurality of semiconductor chips and the substrate, and filling the vent hole; and
forming a plurality of substrate connection terminals on the lower surface of the substrate.

17. The method of claim 16, further comprising, after the forming of the plurality of substrate connection terminals, forming a plurality of substrate-plated layer connection terminals, each of the plurality of substrate-plated layer connection terminals is disposed between the vent hole and a substrate connection terminal of the plurality of substrate connection terminals that is located closest to the vent hole, wherein the plurality of substrate-plated layer connection terminals is connected to the second heat-dissipation layer.

18. The method of claim 16, wherein in the mounting of the plurality of semiconductor chips, the plurality of semiconductor chips has a plurality of chip-plated layer connection terminals further attached thereto,
wherein each of the plurality of chip-plated layer connection terminals is disposed between the vent hole and a chip connection terminal of the plurality of chip connection terminals that is located closest to the vent hole, wherein the plurality of chip-plated layer connection terminals is connected to the first heat-dissipation layer.

19. The method of claim 16, wherein the substrate includes:
a first area, wherein a first semiconductor chip of the plurality of semiconductor chips is mounted in the first area;
a second area, wherein a second semiconductor chip of the plurality of semiconductor chips is mounted in the second area; and
a third area disposed between the first area and the second area, wherein the vent hole is defined in the third area.

20. The semiconductor package of claim 19, wherein each of the plurality of chip connection terminal and the plurality of substrate connection terminals is electrically connected to a ground.
